(19) United States
(12) Patent Application Publication
(10) Pub. No.: US 2007/0209926 A1
(43) Pub. Date: Sep. 13, 2007

(54) Sputter Deposition System and Methods of Use

(75) Inventors: Chih-Ling Lee, Dublin, CA (US); Adrian Devasahayam, Commack, NY (US); Ming Mao, Pleasanton, CA (US)

Correspondence Address: WOOD, HERRON & EVANS, LLP, 2700 CAREW TOWER, 441 VINE STREET, CINCINNATI, OH, 45202, US

(73) Assignee: VEECO INSTRUMENTS, INC., Woodbury, NY (US)

(21) Appl. No.: 11/558,769

(22) Filed: Nov. 10, 2006

Related U.S. Application Data
(63) Continuation-in-part of application No. 11/372,517, filed on Mar. 10, 2006.

(51) Int. Cl. C23C 14/32; C23C 14/00

(52) U.S. Cl. 204/192.1; 204/298.16

(57) ABSTRACT

The present invention relates a physical vapor deposition (PVD) system. e.g. a planetary system, for forming one or more layers of a coating material on a substrate and for treating, or modifying, the substrate surface, which can include the surface of the substrate or a deposited layer of coating material thereon. The PVD system includes a single vacuum (or process) chamber having an ion source and at least one PVD source of the coating material. The ion source, such as a linear ion source, is configured to emit a beam of energetic particles at a substrate for surface modification of the substrate surface, for example, to provide film densification, etching, cleaning, surface smoothing, and/or oxidation thereof. The PVD source(s) of the coating material deposits one or more layers of coating material(s) on the substrate. The uniformity of substrate surface modification and the thickness uniformity of the deposited layers can be maintained by velocity profiling of the rotating substrate within the vacuum chamber.

### CROSS REFERENCE TO RELATED APPLICATIONS

The present application is a continuation-in-part of U.S. patent application Ser. No. 11/372,517, filed Mar. 10, 2006, and titled “SPUTTER DEPOSITION SYSTEM AND METHODS OF USE”, the disclosure of which is hereby incorporated by reference herein in its entirety.

### FIELD OF THE INVENTION

The present invention relates to a sputter deposition system for processing substrates, such as semiconductor wafers and data storage components, and, more particularly, to a system including an ion source and methods of use thereof for surface modification of substrates.

### BACKGROUND OF THE INVENTION

Physical vapor deposition (PVD) modules or systems are used manufacturing sensor elements, for example, for spin-valve giant magnetoresistance (GMR) and tunneling magnetoresistance (TMR) read/write heads for the data storage industry and similar devices. With PVD, typically thin layers or films of magnetic and non-magnetic materials are stacked on a substrate using a sputtering system, which includes a vacuum chamber having one or multiple cathodes. Prior to entering the vacuum chamber, the surface of the substrate may be modified or pre-treated, e.g. etched or cleaned, using an ion source that directs a beam of energetic particles thereat to prepare the surface for receiving a film of sputtered material. The treated substrate then is moved to the vacuum (or process) chamber. Next, material is removed from the source target in the vacuum chamber and subsequently deposited on the substrate to form one or more layers of a desired thickness. After deposition of the one or more layers, the coated substrate may be removed from the vacuum chamber for surface modification via an ion source. Additional layers may be deposited on the modified surface upon returning the substrate to the vacuum chamber.

Surface modification of a substrate surface, which can include the surface of the substrate itself or a deposited layer, is generally performed to modify the physical and/or chemical properties thereof, for example, surface topography, chemical bondings and energy of surface species, etc., giving rise to changes in the packing density, grain size, material phase, microstructure, and, thus, magnetic and electrical properties of deposited or growing films. An ion source, e.g., a linear ion source configured to emit a beam of energetic particles at the substrate surface, may be employed for surface modification of the substrate surface. Surface modification with the linear ion source can simply include energetic particle bombardment, physically sputtering-off high spots, or imparting energy to the surface species for smooth surface or materials phase separation, or growth texture. It can also involve ion beam oxidation in the form of either reactive ion beam oxidation (RIBO) or ion-assisted oxidation (IAO) for oxidizing the surface of the deposited film to a controlled depth, such as to form a sub-nanometer to nanometer thick oxide layer, i.e. an insulator barrier layer or nano-oxide layer (NOL), thereon. In addition, surface modification may also include cleaning of a substrate surface or etching thereof for improved adhesion of a subsequent layer. Also, while the layers that are formed on the substrate should have a highly uniform thickness, it is also desirable that surface modification similarly be highly uniform.

One specific class of conventional PVD modules or systems utilizes planetary sputter deposition which relies on motion providing both an arc shaped movement, i.e. sun rotation, in conjunction with simultaneous spinning, i.e. planet rotation, of the substrate. This compound pattern of movement, or planetary motion, generally provides a desirable thickness uniformity. By way of example, to deposit coating material on a substrate using planetary sputter deposition, a single element or alloyed sputter source of a desired composition may be situated about the periphery of the top or bottom of a cylindrical vacuum chamber. The substrate is placed on a substrate holder that constitutes part of an assembly with a rotary arm. The substrate holder, which is at the end of the rotary arm, spins and generally incorporates provisions to continuously rotate, along with the rotary arm, at relatively high speed about the vacuum chamber azimuthal axis during a deposition cycle. The radius of rotation is such that the center of the substrate is approximately aligned with the center of the sputter source. As the substrate passes or loops by the sputter source, a layer of material defining the element or alloy is sputter deposited on the substrate. Multiple passes may be performed to obtain stacked layers of desired thickness. Multi-layers consisting of component layers with different materials can be deposited by using multiple sputter sources spaced about the vacuum chamber. As described above, surface modification of the substrate and/or of material sputter deposited on the substrate may be performed, as desired, by transferring the substrate back and forth from the vacuum chamber to a separate chamber including an ion source.

Feature size reductions along with a desire to reduce overall production costs in the data storage and semiconductor industries has created a trend to further improve sputter deposition systems, system footprint, and methods associated with sputter depositing material on substrates.

Accordingly, to increase process throughput, to reduce system footprint, and, thus, reduce manufacturing costs, e.g., of microelectronic devices, it is desirable for a PVD system to incorporate both sputter deposition and surface modification into a single vacuum chamber. Such a PVD system should maintain or improve the uniformity of surface modification of current sputtering systems. As discussed above, conventional sputtering systems, however, are designed with surface modification performed in one or more separate chambers outside the sputter deposition chamber. Moving substrates between multiple chambers can cause the substrate and the deposited film to experience a change in base vacuum pressure and temperature. These pressure and temperature changes may result in formation of undesirable interface layers on the processed substrate. In addition, the sputtering system footprint for systems with multiple chambers are overly large and, thus, limiting mass production of microelectronic devices.

What is needed, therefore, is an improved sputter deposition system, such as an improved planetary system, and methods of use thereof to address the above drawbacks of conventional sputter deposition systems wherein the improved system includes a single vacuum chamber configured for both sputter deposition and modification of a substrate surface utilizing an ion source, such system also maintaining or improving the uniformity of the surface modification of current sputtering systems.

### SUMMARY OF THE INVENTION

In accordance with an embodiment of the invention, a system for forming a layer of a coating material on a surface of a substrate and for treating, or modifying, the substrate or deposited film surface includes a physical vapor deposition (PVD) module or tool, e.g. a planetary system, having a single vacuum (or process) chamber which includes at least one ion source and at least one PVD source. The PVD source includes the coating material for depositing the layer on the substrate and, for example, can be a magnetron sputtering apparatus with a sputter target composed of the coating material. The ion source, such as a linear ion source, is configured to emit a beam of energetic particles at a substrate for surface modification, which can include the surface of the substrate or a deposited layer of coating material. Accordingly, the ion source may be utilized, as understood by one of ordinary skill in the art, to modify the physical and/or chemical properties of the substrate surface, for example, to modify surface topography, chemical bondings and energy of surface species, etc., giving rise to changes in the packing density, grain size, material phase, microstructure, and, thus, magnetic and electrical properties of deposited or growing films.

A transport mechanism is situated within the vacuum chamber and is configured to support the substrate therein. The transport mechanism is further configured to move the substrate between a first position spaced from the ion source and a second position spaced from the PVD source. The vacuum chamber further includes a treatment zone across which the substrate is exposed to the beam of energetic particles from the ion source when the substrate is supported at the first position, and a deposition zone across which the substrate is exposed to the coating material from the physical vapor deposition source when the substrate is supported at the second position.

In one example, the vacuum chamber is generally circular such that the chamber includes an azimuthal axis, and the transport mechanism further includes an arm rotatable about the azimuthal axis and a substrate holder attached to the arm at a radius from the azimuthal axis. The substrate holder supports the substrate at the radius as the arm rotates about the azimuthal axis to move the substrate holder to intersect the deposition zone and the treatment zone. The substrate holder may also be configured to spin about a central rotation axis for spinning the substrate as the arm transports the substrate through the deposition zone. In addition, a processor may be provided in communication with the transport mechanism, wherein the processor instructs the transport mechanism to rotate the arm about the azimuthal axis through the treatment and/or deposition zone(s) at least at desired first and second angular velocities. The different velocities provide for substantially uniform modification of the substrate surface and/or for a substantially uniform thickness of the sputtered material on the substrate.

In another example, the vacuum chamber may further include an oxygen inlet associated with the treatment zone of the vacuum chamber to provide, with the assistance of energetic particles, ion-assisted oxidation (IAO) of a layer of coating material. As such, at least a portion of the surface of the coating material on the substrate can be oxidized in this system to provide a nano-oxide layer (NOL), i.e. an insulating oxide layer with small metallic channels. Consequently, a nanoconstricted structure for current-confined-path (CCP) effect in current-perpendicular-to-plane-giant-magnetoresistance (CPP-GMR) spin valve may be provided upon deposition of one or more additional layers onto the NOL. For example, an aluminum copper (AlCu) nano-oxide layer, which includes oxidized aluminum, i.e. aluminum oxide, and small copper channels therein, can be formed on the substrate by ion-assisted oxidation, such NOL ultimately being situated between a pinned layer and a free layer.

Each of the source targets of the present invention can include one or more magnetic and non-magnetic materials of metallic or semi-conductive nature. These materials may be chosen from the elements of Groups 1-15 of the periodic table. The targets are selected based upon the material desired on the substrate. One or more targets may be composed of more than one magnetic and non-magnetic material.

In accordance with a method of the present invention, a substrate initially can be optionally treated, or modified, e.g. cleaned or etched, by directing a beam of energetic particles to the treatment zone defined in the vacuum chamber and exposing the surface of the substrate to the energetic particles therein. Coating material then can be directed to the deposition zone and the substrate surface exposed to the coating material therein, thereby forming a layer comprising the coating material on the surface of the substrate. Next, the beam of energetic particles can be directed to the treatment zone and the coated layer on the substrate exposed thereto in the treatment zone, such as to smooth the surface thereof. One or more additional layers of coating material may be further sputtered onto the substrate and optionally exposed to the beam of energetic particles.

In another embodiment, the coating material on the substrate, for example, an alloy of CuAl, is exposed to an oxygen atmosphere while in the treatment zone to oxidize a portion of the surface of the substrate, with the assistance of the energetic particles, to form a NOL. Similarly, one or more additional layers of coating material may be further sputtered onto the substrate and optionally exposed to the beam of energetic particles.

With the planetary system, the thickness uniformity of the deposited layers and the uniformity of surface modification can be maintained by velocity profiling and by substrate spinning. Specifically, the uniformity may be controlled, using planetary sputter deposition techniques, by adjusting the substrate sweeping velocity at fixed target power or ion source power or vice versa, i.e. by adjusting the target or ion source power at fixed substrate sweeping velocity. As such, the substrate may be transported by the rotary arm about the azimuthal axis through the deposition zone and/or treatment zone at first and second angular velocities to provide, respectively, a substantially uniform thickness of the material on the substrate and/or substantially uniform surface treatment or modification. Accordingly, the above discussed methods can further include moving the substrate through the deposition zone(s) while exposed to the sputtered coating material and/or moving the substrate through the treatment zone while exposed to the energetic particles at first and second angular velocities. In one example, the substrate is rotated through the deposition zone(s) and/or treatment zone at first and second angular velocities about an azimuthal axis in the vacuum chamber. During rotation, the trajectory of the center of the substrate is passing through the center of the source target(s) and ion source(s).

The present invention provides improvements in treatment uniformity, feature dimension control, and symmetry of the treatment properties for symmetrical features on a substrate as found in various data storage and semiconductor structures. In addition, the system is compact with small footprint and can deposit multiple layers of different magnetic and non-magnetic materials on a substrate(s) and treat the substrate surface without removing the substrate from the vacuum chamber, thereby increasing process throughput and, thus, reducing manufacturing costs. As such, the system, and methods of use thereof, overcomes the performance limitations and associated cost disadvantages of other conventional sputter deposition systems.

These and other objects and advantages of the present invention shall become more apparent from the accompanying drawings and description thereof.

### BRIEF DESCRIPTION OF THE DRAWINGS

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 is a perspective view of one embodiment of the sputter deposition system in accordance with the present invention;

FIG. 2 is a schematic plan view of the vacuum chamber of FIG. 1;

FIG. 3 is a schematic cross-sectional view of FIG. 2 taken along line 3-3; and

FIG. 4 is a cross-sectional view of a coated substrate in accordance with a method of the present invention.

### DETAILED DESCRIPTION OF SPECIFIC EMBODIMENTS

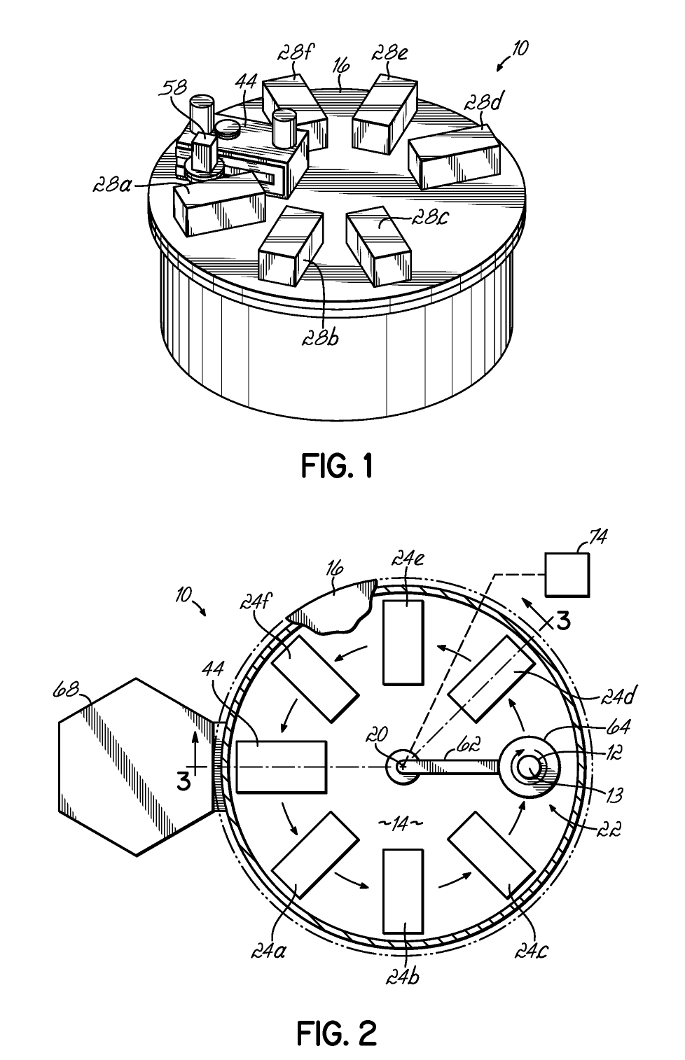

In accordance with one embodiment of the invention, as shown in FIGS. 1-4, a physical vapor deposition (PVD) system 10 is provided for forming one or more layers of a coating material 11a, 11b, 11c, 11d, 11e, 11f, 11g, and 11h on a substrate 12 and for treating, or modifying, the substrate surface, which can include the surface 13 of the substrate 12 surface or a deposited layer of coating material 11a-11h on the substrate 12. A control system (not shown), which has a construction understood by persons having ordinary skill in the art, orchestrates the operation of the PVD system 10.

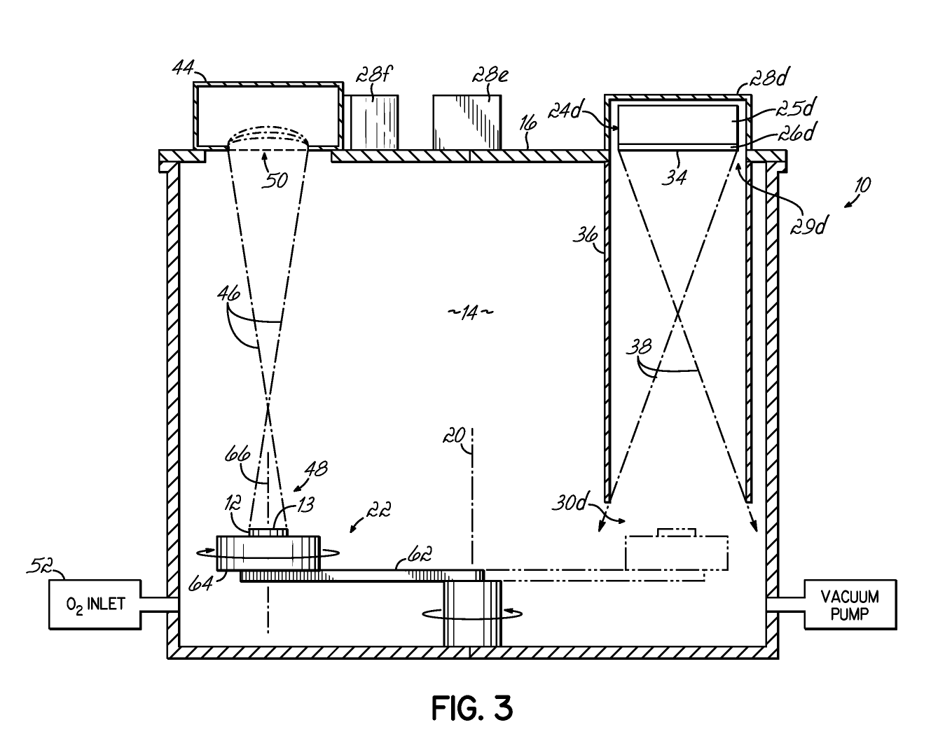

The PVD system 10 includes a vacuum chamber 14 and a chamber lid 16 (shown in partial). The vacuum chamber 14 is generally circular in nature and includes an azimuthal axis 20 about which a transport mechanism 22 is configured to move the substrate 12. The vacuum chamber 14 further defines an evacuable or controlled atmosphere volume. Each of six physical vapor deposition sources, as represented generally be rectangles 24a, 24b, 24c, 24d, 24e, and 24f, e.g., six magnetron sputtering apparatus 25d (only one shown—See FIG. 3) with each having a sputter target 26d (only one shown—See FIG. 3) composed of coating material, for depositing one or more layers of coating material 11a-11h on the substrate 12 are spaced generally about the periphery of the chamber 14 and located within containers 28a, 28b, 28c, 28d, 28e, and 28f situated on the chamber lid 16. The interior of each container 28a-28f is in communication, or association, with the vacuum chamber 14 via corresponding openings 29d (only one shown—See FIG. 3) in the chamber lid 16.

Each physical vapor deposition source 24a-24f is further associated with a deposition zone 30d (only one shown—See FIG. 3) located in the vacuum chamber 14 across which the substrate 12 is exposed to coating material from the target 26d when the substrate 12 is supported at a position spaced therefrom. More or less than six magnetrons 25d with associated sputter targets 26d may be provided depending upon the materials desired to be sputtered on the substrate 12. The PVD-10 planetary process module available from Veeco Instruments, Inc. of Woodbury, N.Y., which is adapted to hold up to ten source targets, is one suitable type apparatus forming a layer(s) of a coating material in accordance with the present invention. In addition, in one example, a rotatable member (not shown) may replace one or more of the individual magnetrons 25d and be configured to position each of a plurality of magnetrons to direct sputtered material from a corresponding sputtering target to the respective deposition zone defined in the vacuum chamber. U.S. Pat. No. 6,328,858, which is hereby incorporated by reference herein in its entirety, describes one suitable type of rotatable member including multiple targets situated thereon for use with the present invention.

Each of the sputter targets 26d (only one shown) can include one or more magnetic and/or non-magnetic materials of metallic or semi-conductive nature. These materials may be chosen, for example, from the elements of Groups 1-15 of the periodic table. The targets 26d are selected based upon the material desired on the substrate 12. One or more targets may be composed of more than one magnetic and non-magnetic material.

As is generally understood in the art, during operation, each magnetron 25d (only one shown), which is positioned behind each source target 26d, provides a magnetic field at the front target surface 34 of the sputtering target 26d. The sputtering target 26d is connected to an electrical power supply (not shown) which, when energized, generates an electric field. The vacuum chamber 14 is evacuated and then filled at a low pressure, typically 0.1 to 10 mTorr, with a suitable inert gas, such as argon, krypton or xenon. The electric field generates a plasma discharge in the inert gas adjacent to the sputtering target 26d. The magnetron 25d supplies a magnetic field that confines and shapes the resulting plasma near the front target surface 34. Positively-charged ions from the plasma are accelerated toward the negatively-biased sputtering target 26d where the ions bombard the front target surface 34 with sufficient energy to sputter atoms of the target material. The flux of sputtered target material travels toward the substrate 12 positioned in opposition to the sputtering target inside the vacuum chamber 14.

A chimney 36 (only one shown) is associated with each source target 26d for confining the sputtered material as represented by arrows 38. Each chimney 36 includes opposing top and bottom openings with the target 26d being provided adjacent the top opening and the bottom opening defining the deposition zone 30d. The substrate 12 is adapted to sweep by each deposition zone 30d, as further explained below, so that the confronting surface 13 of the substrate 12 is exposed to sputtered material 38 that accumulates as a layer or film 11a-11h.

The PVD system 10 for processing the substrate 12 further includes an ion source 44, e.g. a linear ion source such as a linear-argon ion source, situated on the chamber lid 16 and in communication with the vacuum chamber 14 via an opening therein. The ion source 44 is configured to emit a beam of energetic particles as represented by dashed line 46 within a treatment zone 48 in the vacuum chamber 14 when the substrate 12 is supported at a position spaced from the ion source 44. The ion source 44 generally includes an antenna or coil (not shown) that is electrically coupled with a high frequency power supply (not shown), such as a radio frequency (RF) power supply. During operation, a high frequency current supplied to the coil generates a plasma by, for example, inductively coupled radio-frequency excitation of a process gas (e.g. argon) or gas mixture inside the ion source. The high frequency power supply operates at a frequency and at a supplied power contingent upon the operating conditions. The high frequency power supply includes circuitry that controls the power delivered to the coil, thereby permitting the source flux or ion current extracted from the ion source 44 to be modulated by controlled variations in the delivered power. The ion source 44 also has a geometrical shape, i.e. generally rectangular shape, similar to the geometrical shape of aperture 50, which reduces the unused portion of the beam 46 from the ion source 44 that does not treat the substrate 12. Accordingly, the ion source 44 is characterized by a major dimension and a minor dimension and typically has a substantially uniform flux distribution across at least a portion of the major dimension.

The source of beam 46 includes any ion beam source 44 capable of generating energetic particles 46 which can be used to treat the substrate surface 11a-11h or 13, for example, to provide film densification, etching, cleaning, surface smoothing, and/or oxidation thereof. Accordingly, treatment of the substrate surface 11a-11h or 13, as understood by one having ordinary skill in the art, may be used as desired to modify various physical and/or chemical properties, for example, to modify surface topography, chemical bondings and energy of surface species, etc., giving rise to changes in the packing density, grain size, material phase, microstructure, and, thus, magnetic and electrical properties of deposited or growing films. Ion sources 44 suitable for use in the invention include, but are not limited to, the product line of linear ion sources commercially available from Veeco Instruments Inc. (Woodbury, N.Y.), such as the 6×22 cm RF ion source. More than one ion source 44 may be provided with the PVD system 10.

The PVD system 10 further can include an oxygen inlet 52 that is associated with the treatment zone 48 of the vacuum chamber 14 for ion assisted oxidation (IAO) of a layer of coating material 11a-11h. More specifically, the oxygen inlet 52 is configured to deliver oxygen to the treatment zone 48 during emission of energetic particles 46 from the linear ion source 44 when the substrate 12 is supported at a position spaced from the ion source 44 so that a controlled depth of a layer can be oxidized, thereby providing a nano-oxide layer (NOL) as represented by numeral 11e, i.e. an insulating oxide layer with small metallic channels 56. As further discussed below, an aluminum oxide layer with small copper channels can be formed on the substrate by ion-assisted oxidation, such NOL 11e ultimately being situated between a pinned layer as represented by numeral 11d and a free layer as represented by numeral 11f.

With further reference to FIG. 1, a neutralizer 58 may be provided together with the ion source 44 and is associated with the vacuum chamber 14 so as to maintain a neutral atmospheric charge therein, such as during use of the ion source 44. The neutralizer 58, likewise, is situated on the chamber lid 16 and in communication with the vacuum chamber 14 via an opening (not shown) in the lid 16. Additionally, a heating lamp or an additional sputter source (not shown), which could be a RF or DC magnetron or a plurality of them may be provided on the chamber lid 16, such lamp or sputter source similarly being in communication with the vacuum chamber 14 via an opening in the lid. Heating lamp and sputter source, respectively, are used to control the substrate temperature within the chamber 14 and provided for sputtering nonmetallic, or dielectric targets as well as metallic elemental or alloy targets.

As indicated above and further shown in FIGS. 2 and 3, the transport mechanism 22 is situated within the vacuum chamber 14 and configured to support the substrate 12 therein. More specifically, the transport mechanism 22 includes an arm 62 rotatable about the azimuthal axis 20 and a substrate holder 64 attached to the arm 62 at a first radius from the azimuthal axis 20. The substrate holder 64 supports the substrate 12 at the radius as the arm 62 rotates about the azimuthal axis 20, i.e. sun rotation, to move the substrate holder 64 to intersect both the deposition zone 30d at positions spaced from the sputter targets 26d and the treatment zone 48 at a position spaced from the ion source 44. The substrate holder 64 includes a central rotation axis 66 and is configured to spin the substrate 12 thereabout, i.e. planet self-spinning, as the arm 62 moves the substrate holder 64 to intersect the zones 30d, 48. The center of the substrate 12 typically coincides with the central rotation axis 66 when supported by the substrate holder 64. Accordingly, the substrate 12 is adapted to sweep by the zones 30d, 48 so that the confronting surface of the substrate 12 is exposed to deposition fluxes that accumulate as a layer or film 11a-11h and to energetic particles 46 that can modify or treat the substrate surface 11a-11h or 13. U.S. Pat. No. 5,795,448, which is hereby incorporated by reference herein in its entirety, describes the general operation of planetary process modules or devices. Although the PVD system 10 is generally described herein as being a planetary process module which utilizes planet and/or sun rotation, it should be understood that the PVD system 10 may be configured to provide linear transport of the substrate 12 through the vacuum chamber 14 as is known to those having ordinary skill in the art.

The substrate holder 64 may be an electrostatic chuck, which is commonly used in the semiconductor industry. The substrate holder 64 may also include cooling channels (not shown) for carrying cooling fluid. The cooling fluid, such as water, passes through the cooling channel and removes heat from the substrates 12 being processed. In addition, although only one arm 62 is shown, a person of ordinary skill in the art will appreciate that multiple arms similar to arm may be arranged in a hub and spoke arrangement for use in moving multiple substrates through the zones 30d, 48.

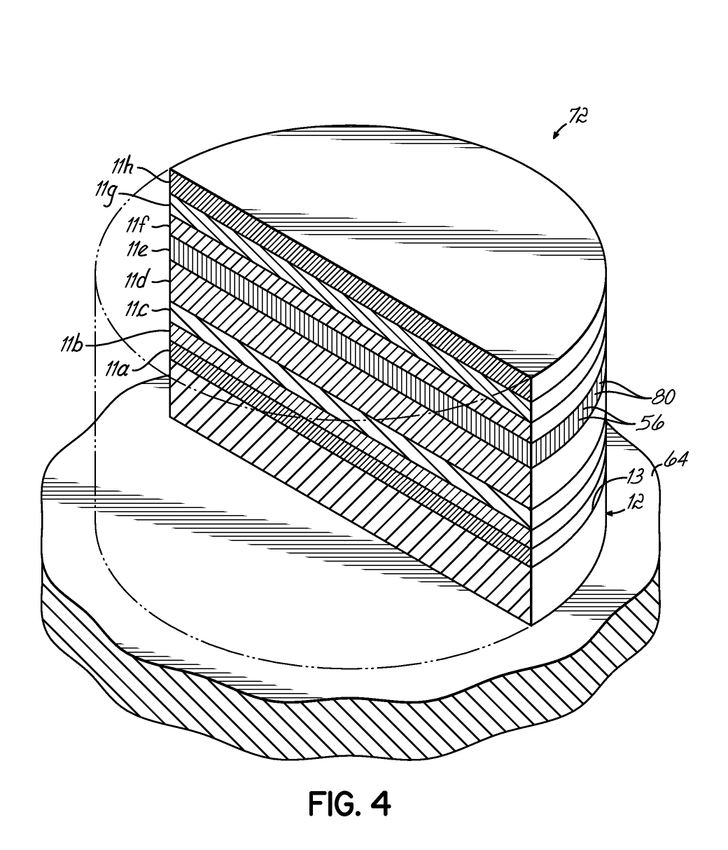

The vacuum chamber 14 may be accessed through a substrate load/unload port 68 that normally is isolated therefrom. The load/unload port 68 is adapted for providing substrates 12 to, and removing coated substrates 72 (see FIG. 4) from, the substrate holder 64 within the chamber 14 such as by way of a transfer robot (not shown) or other means known in the art.

With further reference to FIGS. 2 and 3, a processor 74 in communication, e.g. electrical communication, with the transport mechanism 22 can instruct the transport mechanism 22 to rotate the arm 62 about the azimuthal axis 20 at first and second angular velocities and/or instruct the substrate holder 64 to spin about the central rotation axis 66 at a desired speed through the deposition zones 30d and treatment zone 48. A resulting angular velocity profile represents the instantaneous angular velocity of the rotating substrate as a function of rotation angle over an arc of substrate rotation. The angular velocity of the substrate 12 may be varied systematically with a full rotation of 27 radians of the substrate 12 about azimuthal axis 20. The different angular velocities, as further explained below, can provide for substantially uniform surface modification of the substrate surface 11a-11h or 13 as well as a substantially uniform thickness of the sputtered material on the substrate 12.

With planetary sputter deposition, the substrate 12 typically spins at about 30 to about 1200 rpm about the central rotation axis 66 while rotating at about 0.1 to about 30 rpm about the azimuthal axis 20 as the substrate 12 sweeps by the individual targets 26d and ion beam source 44. However, it should be understood that the planet spinning speed and the sun rotational velocity, respectively, may be less than about 30 rpm and or greater than about 1200 rpm and less than about 0.1 rpm and greater than about 30 rpm. The deposited coating thickness or treatment at any point on the substrate surface 11a-11h or 13 depends on its dwell time beneath, respectively, the source target 26d or ion beam 44 and also on its trajectory thereby. Due to the non-uniform nature of the spatial distribution of a sputtered species and emission of energetic particles, approximately in Gaussian form, substrate rotation about the central rotation axis 66 at a constant velocity is not sufficient for uniform deposition or substrate surface modification. Therefore, a modulation on the substrate rotation is required, and more specifically, the rotation velocity needs to be profiled so that the integral of the sputtered flux 38 and emitted energetic particles 46 over the trajectory of each point on the substrate surface 11a-11h or 13 will be almost the same to ensure, respectively, a substantially uniform film thickness distribution across the substrate 12 and substantially uniform modification of the substrate surface 11a-11h or 13.

Typically, for PVD systems 10 using a constant velocity and substrate 12 of any size, the coating layer is thicker and the substrate surface modification is more pronounced at the center of the substrate 12 becoming, respectively, thinner and less pronounced with increasing radial distance. This is consistent with the perception that the substrate edge spends more time in an outer portion of both the target 26d and the ion beam 44 where the corresponding sputter flux 38 and beam of energetic particles 46 is typically less. Consequently, a velocity profile, such as a 2-step symmetrical profile, may be utilized wherein the substrate 12 is adjusted to travel slower when it first enters the treatment zone 48 and/or deposition zone(s) 30d to allow for longer dwell time for more treatment and deposition, and then speeds up to a desired or normal velocity defining the desired modification and thickness. With the 2-step symmetrical profile, the typical velocity ratio between the desired or maximum velocity and the initial, or slower, velocity is within about 2. For example, if the initial velocity is 5 rpm then the maximum velocity is about 10 rpm. The transition between the two velocities can be either stepwise or gradual. Any multi-step symmetrical or asymmetrical profile may be employed as desired.

An optimization of the substrate surface treatment and/or film thickness uniformity is, therefore, a process of adjusting the velocity ratio to balance the exposure or dwell time of different portions along the radius of the substrate 12. Depending upon the requirement, up to 5 steps or more of the velocity profile can be employed. The uniformity of substrate surface modification and/or thickness uniformity then can be evaluated by methods know to those having ordinary skill in the art.

After optimization of the substrate surface modification and/or deposition uniformity, the emission and/or deposition rate can be calibrated. Typically, two to three offset rotational velocity values are selected, for example, 0.5, 1, and 2 rpm, at a fixed change of rotational velocity value. To achieve a comfortable level of uniformity, a linear regression of the measured thickness or measured modification of the substrate surface 11a-11h or 13, as understood by one of ordinary skill in the art, can be used for rate calibration to determine the deposition rate by sputtered flux or removal rate by energetic particles for the desired offset value to provide a specified layer thickness or substrate surface modification. Optimization and rate recalibration may be required to ensure the best performance.

Accordingly, substrate surface modification, e.g. etching, cleaning, and IAO, and/or the deposited thickness of magnetic or non-magnetic coating material in the present invention may be controlled by adjusting the substrate sweeping velocity at fixed ion beam or target power, thus, allowing for the substrate surface treatment as well as the deposited layers to be substantially uniform. It should also be understood that the thickness uniformity and uniformity of substrate surface modification may also be controlled by adjusting, respectively, the target and ion beam power at fixed substrate sweeping velocity. Accordingly, the uniformity of surface treatment and thickness uniformity of the layers may be maintained by velocity profiling and rotation of the substrate 12 as explained above.

In accordance with a method of the present invention and with reference to FIGS. 2-4, the substrate 12 is provided on the substrate holder 64 and rotated by the arm 62 about the azimuthal axis 20 through the deposition zones 30d (only one shown) during sputter deposition for depositing sputtered material on the substrate 12, and through the treatment zone 48 across which the substrate surface 11a-11h or 13 may be exposed to the beam of energetic particles 46 from the ion source 44. As the substrate 12 moves once around the chamber 14, i.e. performs one pass or loop by physical vapor deposition source 24a-24h, the targets 26d (only one shown) may be sputtered, in sequence, on the substrate 12 in corresponding deposition zones 30d to deposit layers of material 11a-11h having a desired thickness. In addition, as the substrate 12 performs one pass or loop by linear ion beam 44, the ion beam 44 can emit a beam of energetic particles 46 at the substrate 12 in the treatment zone 48 to treat or modify the substrate surface 11a-11h or 13, for example, to smooth the surface of a coating layer 11a-11h. The center of the substrate 12 is approximately aligned with the center of the targets 26d and with the ion beam 44 when the substrate 12 sweeps thereby.

In addition, the processor 74 can instruct the transport mechanism 22 to rotate the arm 62 about the azimuthal axis 20 at first and second angular velocities through both the treatment zone 48 to provide for substantially uniform substrate surface modification and through the deposition zones 30d to provide for substantially uniform thickness of the sputtered material. It should be understood by one skilled in the art that multiple passes by target 26d and/or ion beam 44 can be performed without rotating 360° about the azimuthal axis 20 insofar as the arm 62 may stop during rotation and reverse direction in the chamber 14 as many times as is desired.

One or more layers of coating material 11a-11h also may be exposed to oxygen in the treatment zone 48, via the oxygen inlet 52, while being subjected to energetic particles 46 in an argon atmosphere to oxidize at a controlled depth thereof to provide a nano-oxide layer (NOL), represented by numeral 11e, i.e. an insulating oxide layer with small metallic channels 56, such as an aluminum oxide layer with small copper channels.

The processed substrate 72 may define a spin-valve, e.g. a CPP spin-valve device, wherein plurality of layers 11a-11h have been deposited on substrate 12 and one or more of the layers 11a-11h, including the surface 13 of the substrate 12 may have been treated by the ion source 44 in the PVD system 10. To cause stacking of layers 11a-11h, each layer generally includes a thickness greater than about 5 Å. The processed substrate 72 can include first coating layer or bottom electrode 11a. Second coating layer, or seed layer 11b, is then deposited thereon to provide a foundation to firmly adhere additional layer(s) 11c-11h to the substrate 12 and provide a material microstructure base to enhance the microstructure texture. The third coating layer 11c may define an anti-ferromagnetic material; the fourth coating layer, or pinned layer 11d, can define a ferromagnetic material; the fifth coating layer is insulating layer or nano oxide layer (NOL) 11e; and the sixth coating layer, or free layer 11f, can define a ferromagnetic material.

The free layer 11f has a direction of magnetization that is easier to change than a direction of magnetization of the pinned layer 11d by application of a magnetic field. And, the NOL 11e includes a conducting part, i.e. metallic channels 56, and insulating part 80 with the conduction part 56 having an area that is smaller than an area of the free layer 11f. In addition, seventh coating layer or capping layer 11g typically is sputtered on the substrate 12. As is understood in the art, the capping layer 11g provides a protective covering for the sputtered layer(s) 11a-11f, for example, such as from corrosion due to prolonged exposure to the atmosphere. Finally, eighth layer or top electrode 11h may be provided on capping layer 11g.

For obtaining the CCP effect in the NOL 11e, an AlCu metal alloy, for example, may be deposited, such as from a copper aluminum alloy target, on layer 11d in the corresponding deposition zone. However, it should be understood that alloys or combinations of two or more different materials can be prepared if each pass of the substrate by individual aluminum and copper targets allows a layer to be deposited having a thickness of about an atomic layer so that different materials can intermix at atomic levels, thereby forming homogeneous alloys of desired compositions. The coating layer of copper-aluminum alloy can be subjected to the energetic particles 46, for example, from linear argon-ion beam 44 in the treatment zone 48 and further exposed to oxygen from oxygen inlet 52. The aluminum in the copper-aluminum alloy is oxidized to give aluminum oxide (Al₂O₃), i.e. insulting part 80, with the copper forming metallic channels 56 therein, thereby forming NOL 11e (with embedded copper conductive channels 56). After oxidation, the remaining layers 11f-11h can be deposited in the vacuum chamber 14. IAO, instead of conventional natural oxidation, can realize better purity of the copper metallic channel of the CCP structure due to energy-assist effect of the argon-ion beam 44. More specifically, there is a resulting competition for oxygen between the exposed copper and aluminum atoms. Aluminum oxide forms due to the greater oxygen affinity of aluminum than copper. The copper grains do not oxidize because substantially all available oxygen atoms are captured by aluminum.

A non-limiting example in accordance with the method of the present invention is hereby presented for sputter depositing multilayers 11a-11h on substrate 12, such as for use as a spin valve, composed of magnetic and non-magnetic materials. Specifically, as best shown in FIG. 4, the processed substrate 72 includes substrate 12 and bottom electrode 11a, seed layer 11b, anti-ferromagnetic layer 11c, ferromagnetic layer 11d, NOL 11e, free layer 111f, capping layer 11g, and top electrode 11h. The number of the layers and the thickness of the multi-layers generally depends upon the specific design.

With reference to FIGS. 2-4, the PVD system 10 is provided with six physical vapor deposition sources 24a-24f including, respectively a copper (Cu) target, a nickel-iron-chromium (NiFeCr) alloy target, a platinum-manganese (PtMn) alloy target, a cobalt-iron (CoFe) target 26d (only one shown), an aluminum-copper (AlCu) target, and a tantalum (Ta) target for forming multiple layers 11a-11h on substrate 12. The targets 26d are arranged about the azimuthal axis 20 and the center of the substrate 12 is approximately aligned with the center of each target 26d when the substrate 12 sweeps by each deposition zone 30d (only one shown). A linear argon-ion beam 44 is also provided for treatment of substrate surface 11e and 13.

The substrate 12 is loaded on substrate holder 64 at the load/unload port 68. The substrate 12 may be composed of any material suitable for the purpose(s) of the coated substrate 72. In this example, the substrate 12 is an AlTiC (aluminum-titanium-carbide) wafer and is six inches in diameter. It should be understood that the substrate 12 may be smaller or larger, and/or of a different shape or material, e.g. silicon or glass. Within the chamber 14, the substrate 12 is spun at a desired speed about the central rotation axis 66, such as at about 1200 rpm, with the arm 62 being rotated about the azimuthal axis 20 at specified or optimized angular velocities through the deposition zones 30d and treatment zone 48, as discussed above.

The substrate 12 initially is treated, e.g. cleaned, by directing a beam of energetic particles 46 from linear ion source 44 to the treatment zone 48 defined in the vacuum chamber 14 and exposing the surface 13 of the substrate 12 to the energetic particles 46 therein. More specifically, the processor 74 instructs the transport mechanism 22 to rotate the arm 62 about the azimuthal axis 20 at first and second angular velocities through the treatment zone 48 during emission of energetic particles 46 at the surface 13 to provide for substantially uniform surface cleaning of the substrate 12. For example, the first angular velocity, i.e. initial velocity, may be about 10 rpm until the substrate 12 reaches an offset of about 10° with reference to a linear ion beam centerline. After which point, the arm 62 speeds up to a second angular velocity, i.e. a maximum velocity, of about 20 rpm as it moves through the remainder of treatment zone 48 during emission of particles 46. Then, when the substrate 12 reaches an offset of about −10° with reference to the centerline, the arm 62 slows back down to about 10 rpm.

Following cleaning, each layer 11a-11h then can be deposited on the substrate 12. Accordingly, as the substrate 12 moves once around the chamber 14, i.e. performs one pass or loop by each source target positioned for sputtering, the targets are sputtered, in sequence, at a desired target power (generally a fixed target power from about 50-2000 watts), to deposit a layer of coating material 11a-11h of a desired thickness on the substrate 12. The bottom electrode layer 11a is first sputter deposited on the substrate 12 and defines a sputter deposited layer of Cu.

Next, the NiFeCr, PtMn, and CoFe targets are sputtered in defined sequence on the substrate 12 as the substrate 12 makes one or more passes through the corresponding deposition zones to provide respectively, the seed layer 11b, anti-ferromagnetic layer 11c, and ferromagnetic or pinned layer 11d having desired thicknesses.

Then, the AlCu target is sputtered on layer 11d as the substrate 12 makes a pass through the corresponding deposition zone to provide a coating layer of AlCu. Then, the substrate 12 with its exposed AlCu layer is subjected to ion assisted oxidation in the treatment zone 48. More specifically, the AlCu layer is exposed to a beam of energetic particles 46 in an argon atmosphere in the treatment zone 48 for about 30-45 seconds. The ion beam kinetic energy is no greater than about 35 eV and the ion current less than about 60 mA. Next, oxygen is introduced via the oxygen inlet 52 into the treatment zone 48 during emission of the energetic particles 46 so that the AlCu layer is exposed thereto for about 30 seconds to oxidize the aluminum, thereby providing insulating or nano-oxide layer 11e, i.e. an aluminum oxide layer with small copper channels 56. The ratio of the oxygen to argon can be from about 1:1 to about 1:2 with oxygen being provided in the chamber 14 at about 6-8 sccm. The percent oxygen in the vacuum chamber 14, as understood by one of ordinary skill in the art, depends on the thickness of the alloy layer and the oxidation time of the desired material to be oxidized. Similar to the cleaning of the substrate 12, the processor 74 instructs the transport mechanism 22 to rotate the arm 62 about the azimuthal axis 20 at first and second angular velocities through the treatment zone 48 during ion assisted oxidation to provide for a substantially uniform NOL 11e, whereby the aluminum oxide layer includes discrete and substantially uniform copper channels 56.

After the NOL 11e, the CoFe, Ta, and Cu targets are further sputtered in defined sequence on the substrate as the substrate 12 again makes one or more passes through corresponding deposition zones to provide respectively, the free layer 11f, capping layer 11g, and top electrode 11h having desired thicknesses. Finally, the coated substrate 72 is removed from the vacuum chamber 14 at the load/unload port 68.

The deposited thickness of each layer 11a-11h sputtered on the substrate 12 may be controlled, using planetary sputter deposition techniques, by adjusting the substrate sweeping velocity at fixed target power. The thickness uniformity of the layers 11a-11h is maintained by velocity profiling and by rotation of the substrate 12. The thickness of the material, including the percent composition of each magnetic or non-magnetic material, generally depends upon the specific design. In one example, uniform thickness deviation of the sputter deposited material is no less than about 0.4% and no greater than about 0.6%. In addition, it should be understood by one of ordinary skill in the art that one or more of the layers 11a-11h on the substrate 12 may be further exposed to the beam of energetic particles 46 in the treatment zone 48, as desired, to modify the layer(s) 11a-11h. For example, the capping layer 11g can be subjected to a beam of energetic particles 46 as it sweeps by the linear ion beam 44 in the treatment zone 48, such as to smooth the surface thereof. The uniformity of substrate surface modification may be controlled by adjusting the substrate sweeping velocity through/the treatment zone 48 at fixed ion beam power.

Accordingly, the method of the present invention overcomes the performance limitations of conventional sputter deposition systems wherein the improved system 10 includes single vacuum chamber 14 configured for both sputter deposition and modification of substrate surface 11a-11h or 13 using ion beam 44, such system 10 also maintains or improves the uniformity of the surface modification of current sputtering systems.

While the present invention has been illustrated by a description of various embodiments and while these embodiments have been described in considerable detail, it is not the intention of the applicant to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicant's general inventive concept.

What is claimed is:

1. A system for forming a layer of a coating material on a substrate, comprising:
a vacuum chamber including an ion source configured to emit a beam of energetic particles, and at least one physical vapor deposition source of the coating material for depositing the layer on the substrate; and
a transport mechanism configured to support the substrate inside the vacuum chamber, the transport mechanism further configured to move the substrate between a first position spaced from the ion source and a second position spaced from the physical vapor deposition source;
wherein the vacuum chamber further includes a treatment zone across which the substrate is exposed to the beam of energetic particles from the ion source when the substrate is supported at the first position and a deposition zone across which the substrate is exposed to the coating material from the physical vapor deposition source when the substrate is supported at the second position.

2. The system of claim 1 wherein the physical vapor deposition source further comprises a magnetron sputtering apparatus with a sputter target composed of the coating material.

3. The system of claim 1 wherein the vacuum chamber further includes an azimuthal axis, and the transport mechanism further includes an arm rotatable about the azimuthal axis and a substrate holder attached to the arm at a radius from the azimuthal axis, the substrate holder supporting the substrate at the radius as the arm rotates about the azimuthal axis to move the substrate holder to intersect the deposition zone and the treatment zone.

4. The system of claim 3 further including a processor in communication with the transport mechanism, the processor operative to control the transport mechanism to rotate the arm about the azimuthal axis such that the substrate holder moves through the treatment zone at first and second angular velocities.

5. The system of claim 4 wherein the substrate holder includes a central rotation axis and is further configured to spin the substrate about the central rotation axis as the arm moves the substrate holder to intersect the treatment zone.

6. The system of claim 4 further including a processor in communication with the transport mechanism, the processor operative to control the transport mechanism to rotate the arm about the azimuthal axis such that the substrate holder moves through the deposition zone at first and second angular velocities.

7. The system of claim 6 wherein the substrate holder includes a central rotation axis and is further configured to spin the substrate about the central rotation axis as the arm moves the substrate holder to intersect the deposition zone and the treatment zone.

8. The system of claim 1 further including an oxygen inlet associated with the treatment zone of the vacuum chamber for oxidizing a controlled depth of the layer of coating material on the substrate.

9. The system of claim 1 wherein the ion source is a linear ion source for which the beam of energetic particles is substantially uniform in at least one dimension across the treatment zone.

10. A method for treating a substrate, comprising:
a) directing coating material to a deposition zone defined in a vacuum chamber;
b) exposing the substrate to the coating material in the deposition zone to form a layer comprising the coating material on the substrate;
c) directing a beam of energetic particles to a treatment zone defined in the vacuum chamber; and
d) exposing the layer on the substrate to the energetic particles in the treatment zone.

11. The method of claim 10 further comprising moving the substrate through the deposition zone and moving the substrate through the treatment zone.

12. The method of claim 11 wherein moving the substrate through the treatment zone further comprises:
rotating the substrate about an azimuthal axis of the vacuum chamber while the layer is exposed to the energetic particles in the treatment zone.

13. The method of claim 12 wherein rotating the substrate about the azimuthal axis further comprises:
rotating the substrate about the azimuthal axis at first and second angular velocities while the layer is exposed to the energetic particles in the treatment zone.

14. The method of claim 13 further comprising:
spinning the substrate about a central rotation axis perpendicular to the surface of the substrate while the substrate is rotated about the azimuthal axis through the treatment zone.

15. The method of claim 12 wherein moving the substrate through the deposition zone further comprises:
rotating the substrate about an azimuthal axis of the vacuum chamber while the substrate is exposed to the coating material in the deposition zone.

16. The method of claim 15 wherein rotating the substrate about the azimuthal axis while the substrate is exposed to the coating material in the deposition zone and while the layer is exposed to the energetic particles in the treatment zone, respectively, further comprises:
rotating the substrate about the azimuthal axis through the deposition zone at first and second angular velocities while the substrate is exposed to the coating material, and
rotating the substrate about the azimuthal axis at first and second angular velocities while the layer is exposed to the energetic particles in the treatment zone.

17. The method of claim 16 further comprising:
spinning the substrate about a central rotation axis perpendicular to the surface of the substrate as the substrate is rotated about the azimuthal axis through the deposition zone and the treatment zone.

18. The method of claim 10 wherein exposing the layer on the substrate to the energetic particles in the treatment zone to treat the layer further comprises:
exposing the layer on the substrate to the energetic particles and an oxygen atmosphere in the treatment zone to oxidize a controlled depth of the layer.

19. A method for treating a substrate comprising:
a) directing a beam of energetic particles to a treatment zone defined in the vacuum chamber;
b) exposing the surface of the substrate to the energetic particles in the treatment zone;
c) directing coating material to a deposition zone defined in a vacuum chamber; and
d) exposing the surface of the substrate to the coating material in the deposition zone to form a layer comprising the coating material.

20. The method of claim 19 further comprising moving the substrate through the treatment zone and moving the substrate through the deposition zone.

21. The method of claim 20 wherein moving the substrate through the treatment zone further comprises:
rotating the substrate about an azimuthal axis of the vacuum chamber while the substrate surface is exposed to the energetic particles in the treatment zone.

22. The method of claim 21 wherein rotating the substrate about the azimuthal axis further comprises:
rotating the substrate about the azimuthal axis at first and second angular velocities while the surface of the substrate is exposed to the energetic particles in the treatment zone.

23. The method of claim 22 further comprising:
spinning the substrate about a central rotation axis perpendicular to the substrate surface while the substrate is rotated about the azimuthal axis through the treatment zone.

24. The method of claim 21 wherein moving the substrate through the deposition zone further comprises:
rotating the substrate about an azimuthal axis of the vacuum chamber while the surface of the substrate is exposed to the coating material in the deposition zone.

25. The method of claim 24 wherein rotating the substrate about the azimuthal axis while the surface of the substrate is exposed to the energetic particles in the treatment zone and while the surface of the substrate is exposed to the coating material in the deposition zone, respectively, further comprises:
rotating the substrate about the azimuthal axis at first and second angular velocities while the surface of the substrate is exposed to the energetic particles in the treatment zone; and
rotating the substrate about the azimuthal axis through the deposition zone at first and second angular velocities while the surface of the substrate is exposed to the coating material.

26. The method of claim 25 further comprising:
spinning the substrate about a central rotation axis perpendicular to the surface of the substrate as the substrate is rotated about the azimuthal axis through the treatment zone and the deposition zone.
